(19) United States
(12) Patent Application Publication
(10) Pub. No.: US 2007/0235739 A1
(43) Pub. Date: Oct. 11, 2007

(54) Structure of heat dissipation of implant type light emitting diode package and method for manufacturing the same

(75) Inventors: Tsung-Ting Sun, Chung-Ho City (TW); Hung-Ta Laio, Chung-Ho City (TW); Tz-Shiuan Yan, Chung-Ho City (TW); Po-Jen Su, Chung-Ho City (TW)

Correspondence Address: HDSL, 4331 STEVENS BATTLE LANE, FAIRFAX, VA, 22033, US

(73) Assignee: Edison Opto Corporation

(21) Appl. No.: 11/393,819

(22) Filed: Mar. 31, 2006

(51) Int. Cl. H01L 33/00

(52) U.S. Cl. 257/79

(57) ABSTRACT

A structure of heat dissipation of implant type light emitting diode package having a heat column and a method of manufacturing the same include a substrate, a heat column, and a light emitting diode chip, and the heat column is implanted directly onto a predetermined position of the light emitting diode chip of the substrate and penetrated through both surfaces of a circuit board, and a distal surface of the heat column is coupled with the light emitting diode chip to form a heat conducting end, so that the operating heat produced by a light emitting diode can be dispersed from the package structure through the heat column, so as to achieve an optimal heat dissipating effect.

### BACKGROUND OF THE INVENTION

1. Field of the Invention

The present invention relates to a light emitting diode, and more particular to a structure of heat dissipation of light emitting diode package and a method of manufacturing the same.

2. Description of Prior Art

A light emitting diode (LED) is a solid-state semiconductor device that combines two carriers produced by passing an electric current through the LED to release energy in the form of light. LED has the advantages of a compact size, a fast response rate, and a high-performance feature, and thus the LEDs are applied extensively in different industries. Since LEDs have bottlenecks including insufficient brightness and low luminous efficiency at an early stage, a high power LED is developed later to overcome the drawback of insufficient brightness, and thus LEDs become increasingly popular in the high power illumination market and tend to gradually take over the position of traditional tungsten lamps. LED products have the potential of replacing traditional illumination devices.

As LED manufacturing technologies are improved constantly and new materials are developed, the high power LEDs are developed with enhanced energy capacity and the current passing unit area becomes larger, and thus the heat produced by the chip also becomes larger. As a result, the surrounding of the chip is the best heat dissipating are for the heat produced, but the material used for packing diodes generally adopts resins with an insulating heatproof effect, and the overall heat dissipating effect is poor. If the entire chip and its electrode circuits are wrapped by resins, the heat cannot be dissipated successfully, which will constitute a practically heat-sealed operating environment, and the heat produced will deteriorate the diode. It is one of the main factors affecting the light emitting efficiency of the light emitting diode.

However, the traditional light emitting diode package structure does not come with a heat dissipating structure for dissipating the operating heat produced by the light emitting diode, and thus some manufacturers tried to use improved package materials to conduct the operating heat produced by the light emitting diode to the outside by the high thermal conductivity of the improved material, but the materials used for the package structure still cannot solve the heat dissipating issue due to their low conductivity, or the package materials are expanded by the heat to form a gap between the light emitting diode and the package material, and thus air or moisture may enter into the diode easily and affect the operation of the diode or shorten the life of the light emitting diode. In view of the low heat dissipating performance of the package material, some manufacturers tried to improve the heat dissipating effect by changing the materials of the circuit board, but most circuit boards are made of materials mixed with metal, fiber glass, or ceramic, and the conductivity of such materials is not consistent due to the mixed materials, and the heat dissipating effect is still limited by these materials.

To break through the heat dissipating problem of the foregoing circuit board, R.O.C. Pat. No. 1231609 entitled “Highly conductive PCB SMT light emitting diode” disclosed a structure having a light emitting diode chip, a circuit board, and a highly conductive metal conductor, characterized in that a penetrating hole is disposed at a predetermined position of a light emitting diode chip of a circuit board, and the metal conductor is made by a copper paste, a silver paste, or a high-temperature solder, so that the operating heat produced by the light emitting diode can be conducted to the outside from the circuit board to achieve the expected heat dissipating effect.

In the foregoing prior arts, metal conductor are used to break through the poor thermal conduction of the circuit board, but the technology uses an electroplating process to coat a layer of copper paste, silver paste, or high-temperature solder film onto the internal wall of the penetrating hole, a screen printing technology to introduce a metal paste made of the copper paste, silver paste, or high-temperature solder into the penetrating hole, and a reflow method to form a metal conducting point for the penetrating hole. The structure is manufactured by the manufacturing process technology twice, and thus the manufacture requires much time and labor. Furthermore, the screen printing technology prints a metal paste in the penetrating hole, and thus the metal paste cannot be filled accurately into the penetrating hole and a gap may be produced to give rise to a discontinuous heat conduction. All these are the shortcomings of the prior arts that require further improvements.

### SUMMARY OF THE INVENTION

In view of the foregoing shortcomings of the prior art, the inventor of the present invention based on years of experience in the related industry to conduct experiments and modifications, and finally designed a light emitting diode package structure and a method of manufacturing the same to overcome the shortcomings of the prior art structure.

Therefore, the present invention is to provide a method for quickly producing a structure of heat dissipation of light emitting diode package that directly implants a heat column into a substrate, and thus the manufacture requires the manufacturing process once only and can save a great deal of time and labor. The technology of implanting the heat column can accurately establish a heat conducting path.

Another, the present invention is to provide a structure of heat dissipation of implant type light emitting diode package that directly implants a heat column into a substrate, so that the operating heat produced by the light emitting diode can be guided to the outside directly, and the light emitting power of the packaged light emitting diode will not be affected by the operating heat.

### BRIEF DESCRIPTION OF DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is an exploded view of the present invention;

FIG. 2 is a cross-sectional view of a disassembled structure of the present invention;

FIG. 3 is another cross-sectional view of a disassembled structure of the present invention;

FIG. 4 is a cross-sectional view of an assembled structure of the present invention;

FIG. 5 is a cross-sectional view of a disassembled structure of a substrate of the present invention;

FIG. 6 is an exploded view of a second preferred embodiment of the present invention;

FIG. 7 is another exploded view of a second preferred embodiment of the present invention;

FIG. 8 is a cross-sectional view of an assembled structure of a second preferred embodiment of the present invention;

FIG. 9 is a perspective view of a heat dissipating structure of the present invention;

FIG. 10 is a cross-sectional view of a disassembled structure of a substrate of the present invention;

FIG. 11 is a cross-sectional view of an assembled structure of a substrate of the present invention; and

FIG. 12 is a flow chart of a manufacturing method of the present invention.

### DETAILED DESCRIPTION OF THE NVENTION

The technical characteristics, features and advantages of the present invention will become apparent in the following detailed description of the preferred embodiments with reference to the accompanying drawings.

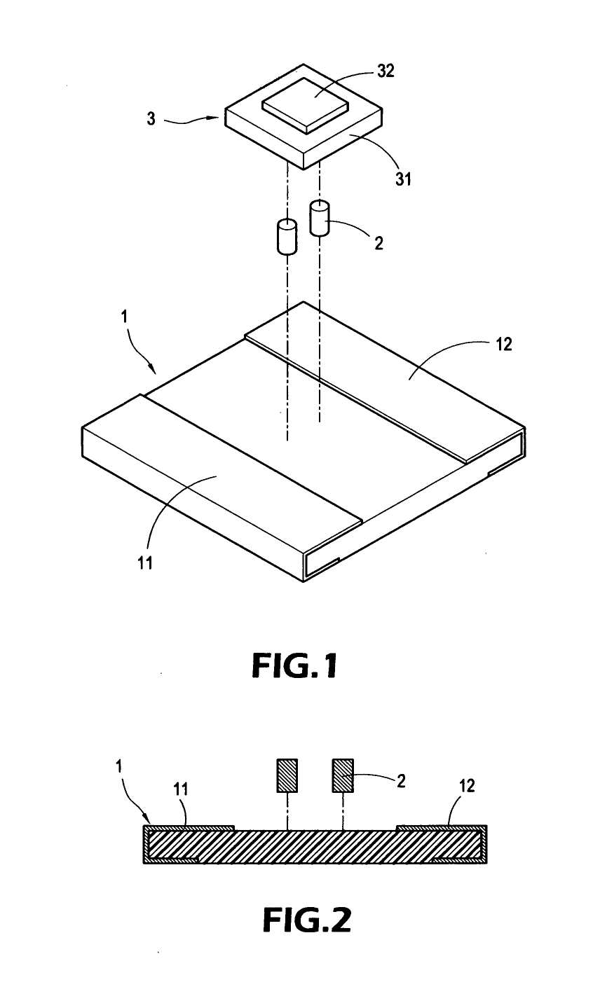

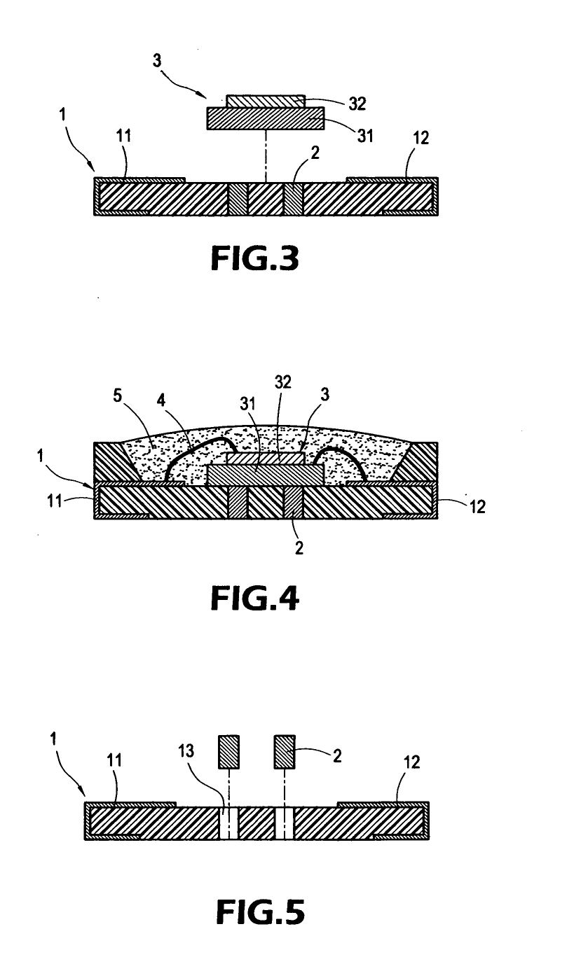

Referring to FIG. 1, a structure of the invention comprises a substrate 1, at least one heat column 2, and a light emitting diode chip 3. The substrate 1 is made of an electric insulating material, which is a printed circuit board in this preferred embodiment, and both left and right ends of the substrate 1 include a first electrode 11 and a second electrode 12 respectively to form an n-shaped structure for covering both ends of the substrate. Referring to FIG. 2, the heat column 2 is implanted directly onto a predetermined position of the light emitting diode chip 3 of the substrate 1 by a manufacturing technology such as a stamping method and penetrated through a predetermined position on both surfaces of the substrate 1. The heat column 2 is made of a highly conducting metal material such as silver, copper, or tin, and the length of the heat column 2 is substantially equal to the thickness of the substrate 1. Referring to FIG. 3, both distal surfaces of the heat column 2 are substantially level with both upper and lower surfaces of the substrate 1. When the light emitting diode chip 3 is installed at a predetermined position of the substrate 1, the N pole 31 at the lower end of the chip 3 is coupled precisely onto the upper distal surface of the heat column 2.

Referring to FIG. 4, the light emitting diode chip 3 is installed at a predetermined position of the substrate 1, and then two conducting wires 4 electrically connect the P pole 32 and the N pole 31 with the first electrode 11 and the second electrode 12, and a shell 5 is used to cover the chip 3 to complete packaging the structure. When the light emitting diode is operated to emit lights, the operating heat produced by the light emitting diode is conducted from a distal surface of the heat column 2 under the N pole 31 to another end of the heat column 2 and dissipated out from the package structure, and both ends of the heat column 2 become a heat conducting end and a heat dissipating end, so that the light emitting power of the light emitting diode will not be affected by the heat produced.

Referring to FIG. 5 for the substrate 1 according to another preferred embodiment of the present invention, an insert hole 13 is produced at a predetermined position of the light emitting diode chip 3 of the substrate 1 and penetrated through both distal surfaces of the substrate 1, and the size of the insert hole 13 is substantially equal to the volume of the heat column 2, and the heat column 2 is precisely contained in the insert hole 13, such that the heat column 2 is installed at the connecting position between the N pole 31 of the light emitting diode and the heat column 2 as shown in FIG. 3. The operating heat produced by the light emitting diode is conducted, so that both distal surfaces of the heat column 2 become a heat conducting end and a heat dissipating end.

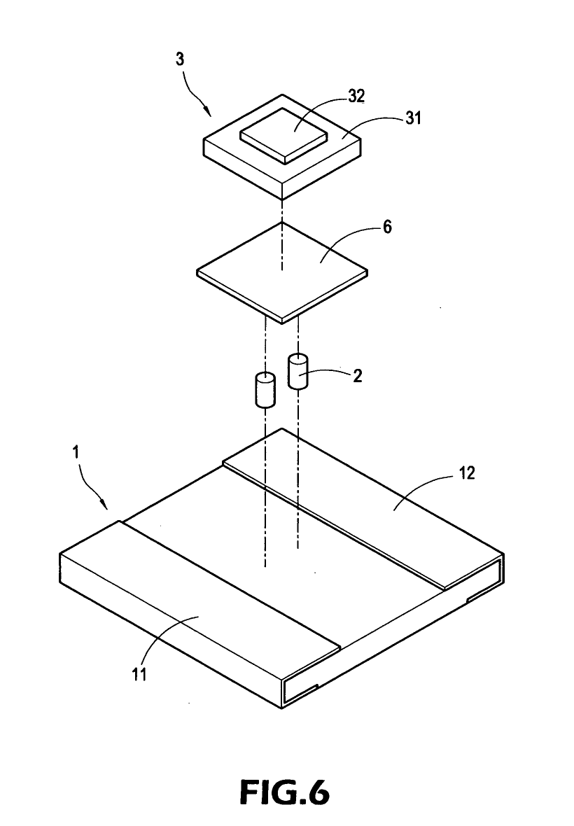

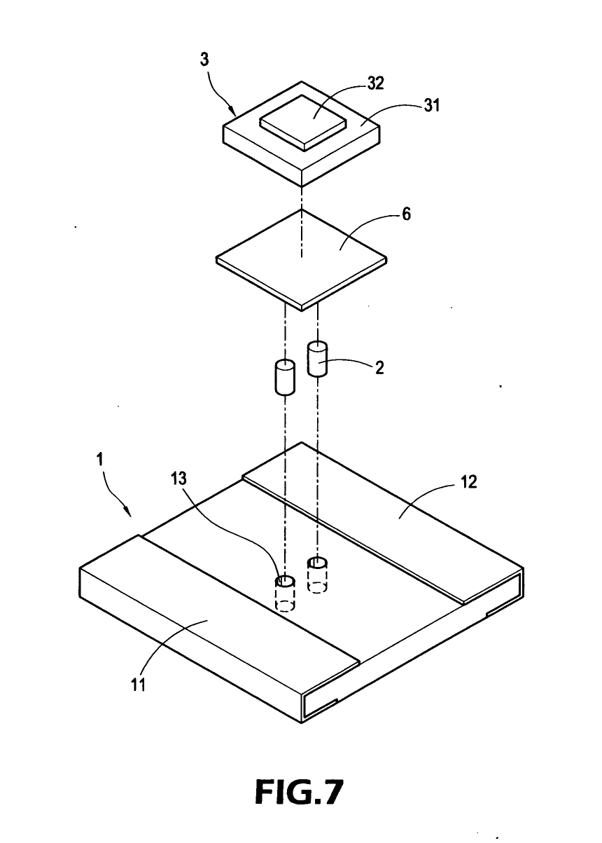

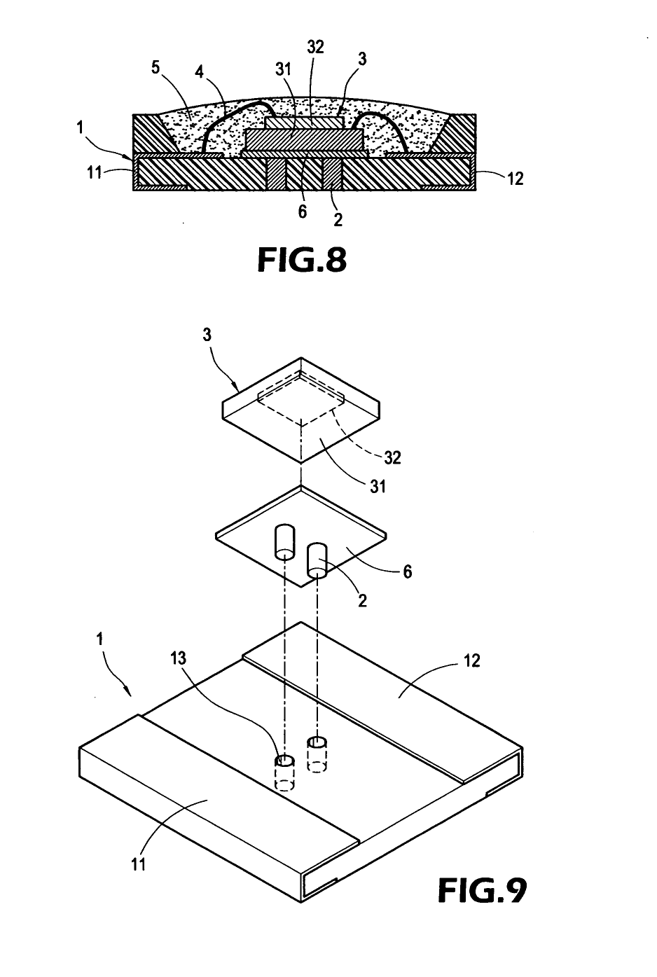

Referring to FIG. 6 for the second preferred embodiment of the present invention, the heat column 2 is implanted directly at a predetermined position of the light emitting diode 3 of the substrate 1, or an insert hole 13 is produced at a predetermined position of the light emitting diode 3 of the substrate 1 as shown in FIG. 7, such that the heat column 2 can be contained in the insert hole 13. The heat column 2 at its top includes a heat sink 6 which is made of a highly conducting material and has an area substantially equal to or slightly larger than the area of the bottom of the light emitting diode chip 3, and the bottom end of the heat sink 6 completely matches with the substrate 1 and the heat column 2, and the heat sink 6 at its top includes a light emitting diode chip 3. Referring to FIG. 8, the foregoing packaging process completes packaging the light emitting diode, such that after the light emitting diode is electrically connected to emit lights, the operating heat produced by the light emitting diode is absorbed by the heat sink 6 under the N pole 31 and then conducted to the heat column 2 connected to the heat sink 6 and finally dissipated out from the package structure.

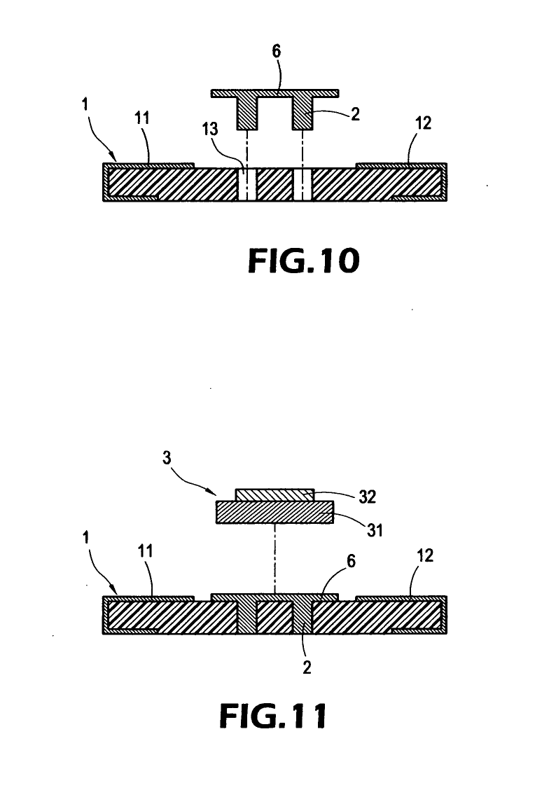

In the foregoing preferred embodiment, the heat column 2 and the heat sink 6 can be integrally formed and manufactured by a high thermal conducting material, and the heat dissipating structure comprised of the heat sink 6 and the heat column 2 is implanted directly into a predetermined position of the light emitting diode chip of the substrate 1. Referring to FIG. 9, an insert hole 13 is produced at a predetermined position of the light emitting diode chip of the substrate 1 for containing the heat column 2. Referring to FIGS. 10 and 11, the heat dissipating structure comprised of the heat sink 6 and the heat column 2 is installed at a predetermined position of the light emitting diode chip of the substrate 1, and then the light emitting diode chip 1 is installed onto the heat sink 6 to complete the package structure by a manufacturing process. Referring to FIG. 8, the heat dissipating structure comprised of the heat sink 6 and the heat column 2 conducts the operating heat produced by the light emitting diode out of the package structure.

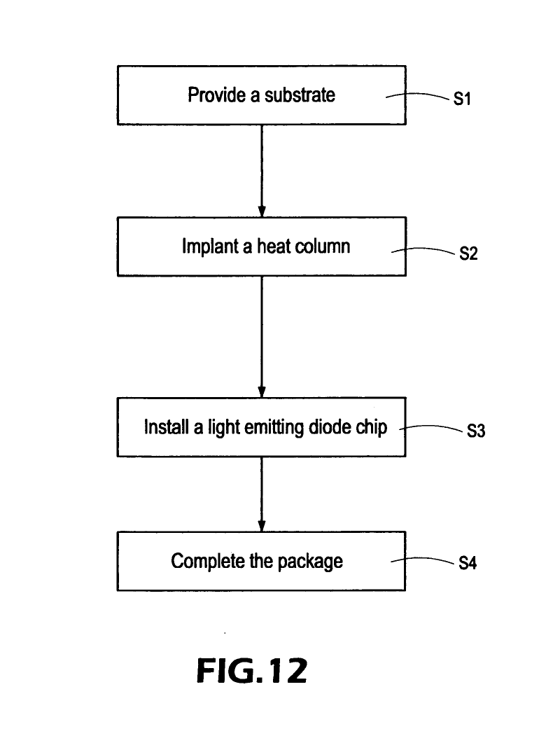

Referring to FIG. 12 for the flow chart of the manufacturing method of the present invention, the method comprises the steps of providing a substrate 1 (S1); using a manufacturing technology such as a stamping technology to produce an insert hole 13 at a predetermined position of the light emitting diode chip 3 of the substrate 1, and implanting the heat column 2 into the substrate 1 (S2), such that the heat column 2 is penetrated directly through the upper and lower surfaces of the substrate 1 and installed at a predetermined position of the light emitting diode chip 3 of the substrate 1 (S3), and coupled to the upper distal surface of the heat column 2, and finally completing the package structure (S4).

The present invention is illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A structure of heat dissipation of a light emitting diode package, comprising:
a substrate;
at least one heat column, embedded into the substrate and penetrated through both distal surfaces of the substrate; and
a light emitting diode chip, installed onto the substrate and coupled to a heat column on the substrate;
such that the operating heat produced by a light emitting diode is conducted to the outside through the heat column.

2. The structure of claim 1, wherein the substrate is made of an electric insulating material.

3. The structure of claim 2, wherein the substrate is a printed circuit board.

4. The structure of claim 1, wherein the substrate further comprises at least one insert hole disposed at a predetermined position of the light emitting diode chip.

5. The structure of claim 4, wherein the insert hole is provided for containing the heat column.

6. The structure of claim 1, wherein the heat column is made of a thermal conducting material.

7. The structure of claim 1, wherein the heat column is made of silver.

8. The structure of claim 1, wherein the heat column is made of copper.

9. The structure of claim 1, wherein the heat column is made of high-temperature solder.

10. The structure of claim 1, further comprising a heat sink installed between the heat column and the light emitting diode.

11. The structure of claim 10, wherein the heat sink and the heat column are made of the same material.

12. The structure of claim 10, wherein the heat sink and the heat column are coupled with each other.

13. The structure of claim 10, wherein the heat sink and the heat column are formed integrally.

14. A method for manufacturing a structure of heat dissipation of a light emitting diode package, comprising the steps of:
providing a substrate;
implanting a heat column directly into a predetermined position of a light emitting diode chip of the substrate by a manufacturing technology;
installing the light emitting diode chip at a predetermined position of the substrate and coupling the heat column; and
packaging the light emitting diode chip onto the substrate.

15. The method of claim 14, wherein the manufacturing technology is a stamping technology.

16. The method of 14, further comprising the steps of:
producing an insert hole at a predetermined position of the light emitting diode chip of the substrate, and implanting the heat column into the insert hole.
